(19) United States
(12) Patent Application Publication
(10) Pub. No.: US 2026/0280509 A1
(43) Pub. Date: Sep. 17, 2026

(54) ACOUSTIC DEVICE PACKAGING STRUCTURE

(71) Applicant: Skyworks Solutions, Inc., Irvine, CA (US)

(72) Inventor: Howard E. Chen, Anaheim, CA (US)

(21) Appl. No.: 19/558,264

(22) Filed: Mar. 5, 2026

Related U.S. Application Data
(60) Provisional application No. 63/769,621, filed on Mar. 10, 2025.

(51) Int. Cl. H03H 1/00; H03F 3/24

(52) U.S. Cl. CPC H03H 1/0007; H03F 3/245; H03F 2200/451

(57) ABSTRACT

A radio frequency filter packaging structure includes signal pads disposed on a first surface of a substrate. The signal pads include a first signal pad positioned near a first side of the substrate. A second signal pad positioned near a second side of the substrate is located away from the first side. A third signal pad is positioned near a third side of the substrate. A fourth signal pad is positioned near a fourth side of the substrate which is located away from the third side. A first elongated ground pad is disposed on the first surface and positioned between the first signal pad and the second signal pad. A second elongated ground pad is disposed on the first surface and positioned between the third signal pad and the fourth signal pad. The first and second elongated ground pads are electrically connected to a ground via a ground connection.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/769,621, filed Mar. 10, 2025, titled “ACOUSTIC DEVICE PACKAGING STRUCTURE,” are hereby incorporated by reference under 37 CFR 1.57 in their entirety.

### BACKGROUND

### Field

The present disclosure generally relates to acoustic wave devices packaging, and particularly to radio frequency filter packaging structures.

### Description of Related Art

Power amplifier duplexer modules are widely employed in low band applications to facilitate the separation of transmitted and received signals while maintaining effective isolation between the input and output terminals. This isolation is important for minimizing signal interference and ensuring efficient operation in communication systems.

In conventional power amplifier duplexer module designs, solder mask defined (SMD) pads are used to merge the ground pins on the surface layer of the substrate. Such a configuration creates a continuous ground plane that acts as an isolation barrier between the input and output terminals, enhancing signal integrity and minimizing cross-talk.

However, certain advanced substrate technologies or packaging requirements may dictate the use of non-solder mask defined (NSMD) pads or require the complete absence of a solder mask. NSMD pads expose more copper for soldering; such a design may eliminate the ability to directly merge ground pins on the surface, thereby compromising the isolation performance of the power amplifier duplexer module.

Accordingly, there is a need for a packaging structure that addresses the limitations of traditional grounding configurations and provides satisfactory isolation performance.

### SUMMARY

The innovations described in the claims each have several aspects, no single one of which is solely responsible for its desirable attributes. Without limiting the scope of the claims, some prominent features of this disclosure will now be briefly described.

According to a number of embodiments of a first aspect, a radio frequency filter packaging structure is provided, the radio frequency filter packaging structure comprising: a substrate having a first surface and a second surface; a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side; at least one first elongated ground pad disposed on the first surface and positioned between the first signal pad and the second signal pad; and at least one second elongated ground pad disposed on the first surface and positioned between the third signal pad and the fourth signal pad, a ground connection via which the first and second elongated ground pads are electrically connected to a ground.

According to a number of embodiments of a second aspect, a power amplifier duplexer module comprising a radio frequency filter packaging structure is provided. The radio frequency filter packaging structure includes: a substrate having a first surface and a second surface, a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side, at least one first elongated ground pad disposed on the first surface and positioned between the first signal pad and the second signal pad, at least one second elongated ground pad disposed on the first surface and positioned between the third signal pad and the fourth signal pad, and a ground connection via which the first and second elongated ground pads are electrically connected to a ground. The power amplifier duplexer module also comprises a transmitter component connected to the first signal pad, a receiver component connected to the second signal pad, a first antenna connected to the third signal pad, and a second antenna connected to the fourth signal pad.

According to a number of embodiments of a third aspect, a wireless mobile device comprising a radio frequency filter packaging structure is provided. The radio frequency filter packaging structure includes: a substrate having a first surface and a second surface, a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side, at least one first elongated ground pad disposed on the first surface and positioned between the first signal pad and the second signal pad, at least one second elongated ground pad disposed on the first surface and positioned between the third signal pad and the fourth signal pad, and a ground connection via which the first and second elongated ground pads are electrically connected to a ground.

Embodiments of the filter packaging structure disclosed herein may address various problems. One or more embodiments may address one or more of the problems concerning separation of transmission and reception paths within a packaging structure. One or more embodiments may also address problems concerning maintaining high isolation between input and output terminals within a packaging structure to minimize interference and prevent signal degradation.

In some aspects, the techniques described herein relate to a radio frequency filter packaging structure including: a substrate having a first surface and a second surface; a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side; at least one first elongated ground pad disposed on the first surface and positioned between the first signal pad and the second signal pad; at least one second elongated ground pad disposed on the first surface and positioned between the third signal pad and the fourth signal pad; and a ground connection via which the first and second elongated ground pads are electrically connected to a ground.

In some embodiments, the techniques described herein relate to a radio frequency filter packaging structure wherein the first elongated ground pad includes at least two first ground pads and a conductive bar extending between the at least two first ground pads.

In some embodiments, the techniques described herein relate to a radio frequency filter packaging structure wherein the at least two first ground pads and the conductive bar extending between the at least two first ground pads are integrally formed.

In some embodiments, the techniques described herein relate to a radio frequency filter packaging structure wherein the second elongated ground pad includes at least two second ground pads and a conductive bar extending between the at least two second ground pads.

In some embodiments, the techniques described herein relate to a radio frequency filter packaging structure wherein the at least two second ground pads and the conductive bar extending between the at least two second ground pads are integrally formed.

In some embodiments, the techniques described herein relate to a radio frequency filter packaging structure wherein the first and second elongated ground pads are provided in the form of an integrated ground pad.

In some embodiments, the techniques described herein relate to a radio frequency filter packaging structure wherein the integrated ground pad includes at least one first elongated portion positioned between the first signal pad and the second signal pad.

In some embodiments, the techniques described herein relate to a radio frequency filter packaging structure wherein the integrated ground pad includes at least one second elongated portion positioned between the third signal pad and the fourth signal pad.

In some embodiments, the techniques described herein relate to a radio frequency filter packaging structure wherein the first elongated portion has a width equal to or wider than the first and second signal pads.

In some embodiments, the techniques described herein relate to a radio frequency filter packaging structure wherein the second elongated portion has a width equal to or wider than the third and fourth signal pads.

In some embodiments, the techniques described herein relate to a radio frequency filter packaging structure wherein the first elongated ground pad has a width equal to or wider than the first and second signal pads.

In some embodiments, the techniques described herein relate to a radio frequency filter packaging structure wherein the second elongated ground pad has a width equal to or wider than the third and fourth signal pads.

In some embodiments, the techniques described herein relate to a radio frequency filter packaging structure wherein the first elongated ground pad and the second elongated ground pad are formed by merging a plurality of ground pads formed on the first surface of the substrate.

In some embodiments, the techniques described herein relate to a radio frequency filter packaging structure wherein the substrate includes a ground plane electrically connected to the ground.

In some embodiments, the techniques described herein relate to a radio frequency filter packaging structure wherein the substrate includes one or more interconnects, at least one of the one or more interconnects being electrically connected to the ground.

In some embodiments, the techniques described herein relate to a radio frequency filter packaging structure wherein the first elongated ground pad is electrically connected to the at least one of the one or more interconnects electrically connected to the ground.

In some embodiments, the techniques described herein relate to a radio frequency filter packaging structure wherein the first elongated ground pad is electrically connected to the one or more interconnects by one or more vias.

In some embodiments, the techniques described herein relate to a radio frequency filter packaging structure wherein the second elongated ground pad is electrically connected to the at least one of the one or more interconnects electrically connected to the ground.

In some embodiments, the techniques described herein relate to a radio frequency filter packaging structure wherein the second elongated ground pad is electrically connected to the one or more interconnects by one or more vias.

In some embodiments, the techniques described herein relate to a radio frequency filter packaging structure wherein the ground connection is coupled to the first elongated ground pad away from the substrate.

In some embodiments, the techniques described herein relate to a radio frequency filter packaging structure wherein the ground connection is coupled to the second elongated ground pad away from the substrate.

In some embodiments, the techniques described herein relate to a radio frequency filter packaging structure wherein the substrate includes a layer having a multilayer organic and/or ceramic structure.

In some embodiments, the techniques described herein relate to a radio frequency filter packaging structure including an interior layer having one or more electrical connections formed therein.

In some embodiments, the techniques described herein relate to a radio frequency filter packaging structure wherein the electrical connections formed within the interior layer are configured to route signals between the signal pads and external circuitry.

In some aspects, the techniques described herein relate to a power amplifier duplexer module including a radio frequency filter packaging structure, the radio frequency filter packaging structure including: a substrate having a first surface and a second surface, a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side, at least one first elongated ground pad disposed on the first surface and positioned between the first signal pad and the second signal pad, at least one second elongated ground pad disposed on the first surface and positioned between the third signal pad and the fourth signal pad, and a ground connection via which the first and second elongated ground pads are electrically connected to a ground; a transmitter component connected to the first signal pad; a receiver component connected to the second signal pad; a first antenna connected to the third signal pad; and a second antenna connected to the fourth signal pad.

In some embodiments, the techniques described herein relate to a power amplifier duplexer module wherein the power amplifier duplexer module is a low band power amplifier duplexer module.

In some embodiments, the techniques described herein relate to a power amplifier duplexer module wherein the first antenna and the second antenna are configured to receive signals of different frequency bands.

In some embodiments, the techniques described herein relate to a power amplifier duplexer module including a plurality of third signal pads, each of the plurality of third signal pads being connected to a different transmitter component.

In some embodiments, the techniques described herein relate to a power amplifier duplexer module including a plurality of fourth signal pads, each of the plurality of fourth signal pads being connected to a different receiver component.

In some aspects, the techniques described herein relate to a wireless mobile device including a radio frequency filter packaging structure, the radio frequency filter packaging structure including: a substrate having a first surface and a second surface, a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side, at least one first elongated ground pad disposed on the first surface and positioned between the first signal pad and the second signal pad, at least one second elongated ground pad disposed on the first surface and positioned between the third signal pad and the fourth signal pad, and a ground connection via which the first and second elongated ground pads are electrically connected to a ground.

In some aspects, the techniques described herein relate to a radio frequency device including: a first transmit-receive pad pair including a first transmit signal pad and a first receive signal pad; a second transmit-receive pad pair including a second transmit signal pad and a second receive signal pad; and a ground pad structure including a first portion having a first ground pad, a second ground pad, and a conductive bar extending between the first ground pad and the second ground pad, the first portion positioned between the first transmit signal pad and a first receive signal pad.

In some embodiments, the techniques described herein relate to a radio frequency device wherein the first portion of the ground pad structure is positioned between the second transmit signal pad and the second receive signal pad.

In some embodiments, the techniques described herein relate to a radio frequency device wherein the ground pad structure further includes a second portion having a third ground pad, a fourth ground pad, and a second conductive bar extending between the third ground pad and the fourth ground pad.

In some embodiments, the techniques described herein relate to a radio frequency device wherein the first portion and the second portion are electrically coupled by a third conductive bar.

In some embodiments, the techniques described herein relate to a radio frequency device further including a carrier portion and a device portion coupled to the carrier portion, wherein the first portion and the second portion are located on a surface of the carrier portion opposite the device portion.

In some embodiments, the techniques described herein relate to a radio frequency device wherein the first portion and the second portion are electrically coupled by a ground interconnect structure embedded in the carrier portion.

In some embodiments, the techniques described herein relate to a radio frequency device wherein a maximum lateral dimension of the first portion of the ground pad structure is greater than a maximum lateral dimension of the first transmit signal pad.

In some embodiments, the techniques described herein relate to a radio frequency device wherein the maximum lateral dimension of the first portion is at least 1.5 times greater than the maximum lateral dimension of the first transmit signal pad.

In some embodiments, the techniques described herein relate to a radio frequency device further including a first antenna pad and a second antenna pad, wherein the ground pad structure is at least partially positioned between the first antenna pad and the second antenna pad.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 illustrates a top view of an example radio frequency filter packaging structure having solder mask defined pads and flooded ground (prior art);

FIG. 2 illustrates a top view of an example radio frequency filter packaging structure having non-solder mask defined pads and no flooded ground (prior art);

FIG. 3A illustrates a top view of an example radio frequency filter packaging structure, according to an embodiment;

FIGS. 3B and 3C are schematic cross-sectional side views of the radio frequency filter packaging structure of FIG. 3A taken along different cross-sections;

FIG. 4 illustrates a top view of an example radio frequency filter packaging structure, according to another embodiment;

FIG. 5 is a schematic plan view of a radio frequency filter packaging structure that includes an “I”-shaped integrated elongated ground pad;

FIG. 6 is a schematic plan view of a radio frequency filter packaging structure that includes an integrated elongated ground pad having another shape;

FIG. 7 is a radio-frequency front end module according to an embodiment; and

FIG. 8 is a wireless device according to an embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The present disclosure relates to a signal isolation structure for radio frequency filter packaging, which may be used in power amplifier duplexer (PAD) modules for low band (LB) applications. In such applications, it is important to provide effective separation of transmission and reception paths while maintaining high isolation between input and output terminals to minimize interference and prevent signal degradation.

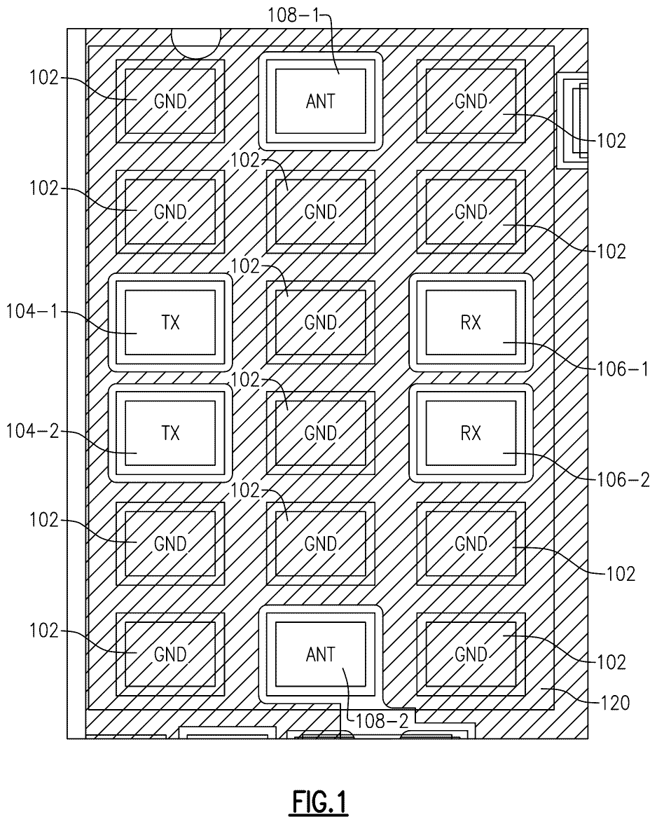

PAD modules often utilize solder mask defined (SMD) pads for grounding arrangements. These SMD pads may facilitate the direct merging of ground (GND) pins on the metallic layer, thereby forming a continuous ground plane that acts as an isolation barrier between the input and output terminals. This approach is straightforward and reliable, provided that the substrate technology and packaging support the use of SMD pads. As illustrated in FIG. 1, an example of such a packaging structure comprises a flooded ground 102 with antenna pads 108-1, 108-2, transmitter pads 104-1, 104-2, and receiver pads 106-1, 106-2.

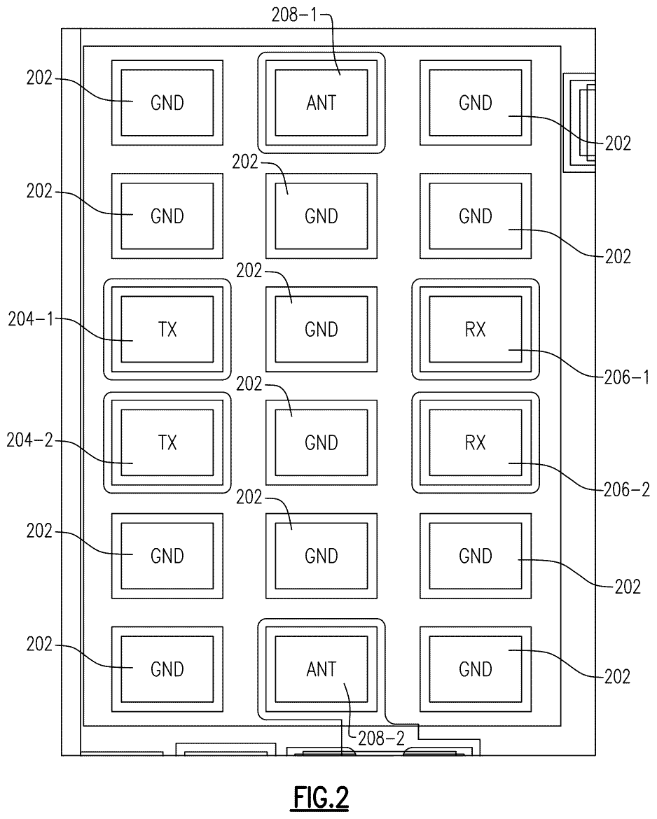

However, when substrate or packaging technologies require the use of non-solder mask defined (NSMD) pads or the complete omission of the solder mask, the ability to merge GND pins at the surface layer may be lost. This disruption may compromise the isolation barrier, resulting in degraded isolation performance. As shown in FIG. 2, an example of such a packaging structure with NSMD pads comprises ground pads 202 without ground flooding, having antenna pads 208-1, 208-2, transmitter pads 204-1, 204-2, and receiver pads 206-1, 206-2.

To address this issue, the ground plane is often relocated to an internal layer within the substrate stack. However, relocating the ground plane introduces several design challenges. For example, vias must be accurately aligned to connect the GND pins to the buried ground plane, and signal traces must be carefully routed to minimize interference. Additionally, the redistribution of signal and ground layers may increase design complexity and may impact the overall size and cost of the PAD module.

An alternative approach involves soldering the PAD to a copper sheet treated with an organic surface preservative (OSP) to prevent oxidation. However, this method can result in poor yield and reliability.

The present disclosure relates to an acoustic device signal isolation structure designed to separate signal paths within packaged acoustic devices, such as frequency duplex (FD) filters. This structure addresses challenges associated with achieving high isolation performance in packaging configurations where traditional ground flood merging is not feasible due to substrate or packaging design constraints.

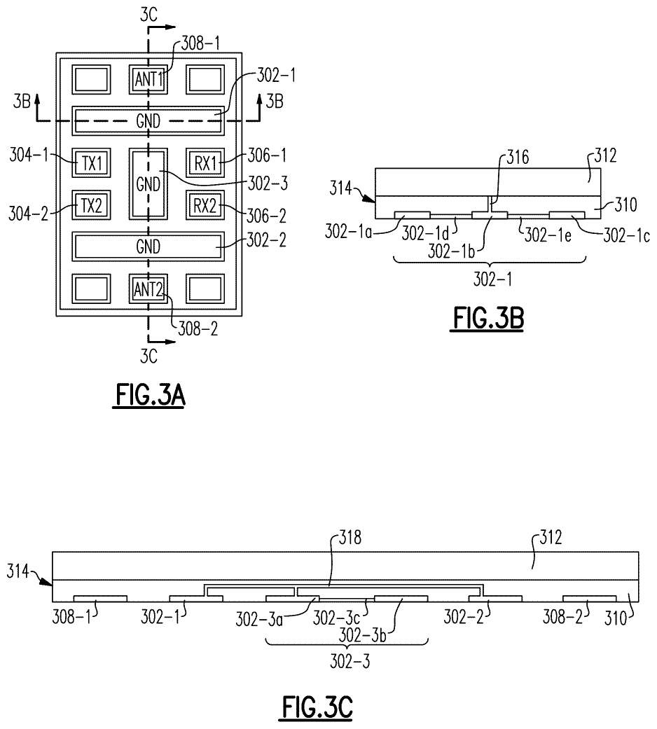

FIG. 3A illustrates a top view of an example radio frequency filter packaging structure according to an embodiment. FIGS. 3B and 3C are schematic cross-sectional side views of the radio frequency filter packaging structure of FIG. 3A taken along different cross-sections. As shown in FIG. 3A, the radio frequency filter packaging structure comprises a substrate on which a plurality of signal pads 304, 306, 308 are disposed. The plurality of signal pads 304, 306, 308 may be distributed at multiple locations on the substrate. In particular, the signal pads 304, 306, 308 include a first signal pad 304-1 and a second signal pad 306-1 positioned near a first side and a second side of the substrate, respectively.

It will be appreciated that the term “substrate” as used herein does not necessarily refer to a structure made of a single material, but may be made of a plurality of materials; and/or comprise multiple layers and/or structures therein; and/or be mounted to another structure. It will also be understood that the term “pad” as used herein, for example, in “antenna pad,” “signal pad,” or “ground pad,” is not intended to limit the physical shape or dimensions thereof, and it will be appreciated that such pads can be provided in any other suitable shapes and dimensions (e.g., pins).

As illustrated in FIG. 3A, the radio frequency filter packaging structure may also comprise a ground pad structure that includes at least one first elongated ground pad 302-3 disposed on the first surface and positioned between the first signal pad 304-1 and the second signal pad 306-1 to provide electromagnetic isolation between the first and second signal pads. The ground pad structure can also include ground pads 302-1, 302-2. Although the example of FIG. 3A may relate to an embodiment having one first elongated ground pad 302-3, it will also be appreciated that, in other embodiments, the radio frequency filter packaging structure may comprise one first elongated ground pad 302-3 or a greater number of first elongated ground pads 302-3.

As illustrated in the example of FIG. 3A, the radio frequency filter packaging structure and/or its substrate may have a rectangular shape. In such cases, the first and second sides of the substrate may correspond to two opposite sides of the substrate. However, it will be appreciated that, in other embodiments, the radio frequency filter packaging structure and/or its substrate may have a non-rectangular shape, in which case the first and second sides of the substrate may not correspond to two directly opposite sides. Instead, the first and second sides of the substrate may correspond to sides between which there is a region sufficient to position at least one first elongated ground pad between the first signal pad 304-1, which is located near the first side, and the second signal pad 306-1, which is located near the second side.

The signal pads 304, 306, 308 may be configured to accommodate connection(s) with one or more component(s) having different functions. For example, as shown in FIG. 3A, the first signal pad 304-1 may be configured to be connected to a transmitter component and the second signal pad 306-1 may be configured to be connected to a receiver component.

As shown in the example of FIG. 3A, the radio frequency filter packaging structure may comprise more than one first signal pad 304-1, 304-2 and/or more than one second signal pad 306-1, 306-2. In such cases, each of the first signal pads 304-1, 304-2 may be configured to be connected to a transmitter component, and each of the second signal pads 306-1, 306-2 may be configured to be connected to a receiver component. Alternatively, the first signal pads 304-1, 304-2 may be configured to be connected to the same transmitter component, and the second signal pads 306-1, 306-2 may be configured to be connected to the same receiver component. In some embodiments, the first signal pad 304-1 and the second signal pad 306-1 can operate at substantially the same frequency band, and the first signal pad 304-2 and the second signal pad 306-2 can operate at substantially the same frequency band. For example, the first signal pad 304-1 and the second signal pad 306-1 can operate in a first frequency band, and the first signal pad 304-2 and the second signal pad 306-2 can operate in a second frequency band different from the first frequency band. In the absence of the at least one first elongated ground pad 302-3, there can be significant electromagnetic coupling between the first signal pad 304-1 and the second signal pad 306-1, between the first signal pad 304-2 and the second signal pad 306-2, between the first signal pad 304-1 and the second signal pad 306-2, and/or between the first signal pad 304-2 and the second signal pad 306-1. In some embodiments, the first signal pad 304-1 and the second signal pad 306-1 can define a first transmit-receive pad pair, and the first signal pad 304-2 and the second signal pad 306-2 can define a second transmit-receive pad pair It will also be appreciated that, although the embodiments discussed herein may relate to examples with one or two first signal pads 304-1, 304-2 and one or two second signal pads 306-1, 306-2, in other embodiments, the radio frequency filter packaging structure may comprise a greater number of first signal pads 304-1, 304-2 and/or a greater number of second signal pads 306-1, 306-2.

The signal pads 304, 306, 308 also include a third signal pad 308-1 and a fourth signal pad 308-2 positioned near a third side and a fourth side of the substrate, respectively. As illustrated in FIG. 3A, the radio frequency filter packaging structure includes one or more first elongated ground pads 302-3 and/or one or more second elongated ground pads 302-1, 302-2 positioned between the third signal pad 308-1 and the fourth signal pad 308-2 to provide electromagnetic isolation between the third and fourth signal pads 308-1, 308-2. The first elongated ground pad 302-3 and/or one or more second elongated ground pads 302-1, 302-2 may be electrically connected to a ground plane positioned within an interior layer of the substrate.

Although the embodiment illustrated in FIG. 3A relates to an example with only one first elongated ground pad 302-3, it will be appreciated that, in other embodiments, the radio frequency filter packaging structure may comprise a greater number of first elongated ground pads 302-3 than the one shown in FIG. 3A.

In the case where the substrate has a rectangular shape as shown in FIG. 3A, the third side and the fourth side of the substrate may correspond to two opposite sides of the substrate. However, it will be appreciated that, in other embodiments, the radio frequency filter packaging structure and/or its substrate may have a non-rectangular shape, in which case the third and fourth sides of the substrate may not correspond to two directly opposite sides. Instead, the third and fourth sides of the substrate may correspond to sides between which there is a region sufficient to position one or more second elongated ground pads 302-1, 302-2 between the at least one third signal pad 308-1 and the at least one fourth signal pad 308-2.

The third signal pad 308-1 and the fourth signal pad 308-2 may be configured to accommodate connection(s) with one or more components having different functions. For example, as shown in FIG. 3A, the third signal pad 308-1 may be configured to be connected to a first antenna component, and the fourth signal pad 308-2 may be configured to be connected to a second antenna component.

It will be appreciated that the radio frequency filter packaging structure may comprise more than one third signal pad 308-1 and/or more than one fourth signal pad 308-2. In such cases, each of the third signal pads 308-1 may be configured to be connected to a different antenna component, and each of the fourth signal pads 308-2 may be configured to be connected to another antenna component. Alternatively, the third signal pads 308-1 may be configured to be connected to the same antenna component, and the fourth signal pads 308-2 may be configured to be connected to the same antenna component. Still alternatively, the third signal pads 308-1 and the fourth signal pads 308-2 may all be configured to be connected to the same antenna component.

It will also be appreciated that, although the embodiment illustrated in FIG. 3A relates to an example with only one third signal pad 308-1 and only one fourth signal pad 308-2, in other embodiments, the radio frequency filter packaging structure may comprise a greater number of third signal pads 308-1 and/or a greater number of fourth signal pads 308-2.

The radio frequency filter packaging structure comprises a ground connection via which the first elongated ground pad 302-3 and the second elongated ground pads 302-1, 302-2 are electrically connected to a ground. Optionally, the ground connection may be, include, or be connected to a ground plane. Such a ground plane may be positioned within the substrate, or the radio frequency filter packaging structure may comprise an interior layer including a ground plane. Optionally, the ground connection may be provided via one or more conductive paths, such as vias, extending between the first surface of the substrate and the ground plane.

The radio frequency filter packaging structure can include a carrier portion 310 and a device portion 312. In some embodiments, the carrier portion 310 can include a routing layer 314. For example, the routing layer 314 can include an interconnect layer, or a re-distribution layer (RDL). The routing layer 314 can include vias between the pads in the carrier portion 310 to the device portion 312. For example, the routing layer 314 can include a via 316 that electrically couples the second elongated ground pad 302-1 to the device portion 312. The routing layer 314 can include the ground connection. For example, the ground connection can be provided as a ground interconnect structure 318 that couples the first elongated ground pad 302-3 and the second elongated ground pads 302-1, 302-2. In some embodiments, the ground interconnect structure 318 can be embedded in the carrier portion 310.

The first elongated ground pad 302-3 may be formed by merging at least two first ground pads. For example, the first elongated ground pad 302-3 may be formed by depositing conductive materials between the at least two first ground pads to form a conductive bar or an equivalent elongated structure, which will be referred to as a conductive bar as described herein. Thus, the first elongated ground pad 302-3 may comprise at least two first ground pads and a conductive bar extending between the at least two first ground pads. The at least two first ground pads and the conductive bar extending between the at least two first ground pads may be integrally formed.

The second elongated ground pad 302-1, 302-2 may be formed by merging at least two second ground pads. For example, the second elongated ground pad 302-1, 302-2 may be formed by depositing conductive materials between the at least two second ground pads to form a conductive bar or an equivalent elongated structure, which will be referred to as a conductive bar as described herein. Thus, the second elongated ground pad 302-1, 302-2 may comprise at least two second ground pads and a conductive bar extending between the at least two second ground pads.

Thus, the at least two second ground pads and the conductive bar extending between the at least two second ground pads may form an integral, conductive structure as a result of such merging. The conductive bar and the second ground pads may optionally be of the same material, or the materials of the second ground pads and the conductive bar may be selected to facilitate easy merging or to enhance the integrity of the elongated ground pad. For example, the selection of materials may consider factors such as thermal expansion coefficients. The materials may also be chosen to provide satisfactory electrical properties for the ground pad.

For example, the second elongated ground pad 302-1 can include ground pads 302-1a, 302-1b, 302-1c and conductive bars 302-1d, 302-1e. The conductive bars 302-1d, 302-1e can electrically connect adjacent ones of the ground pads 302-1a, 302-1b, 302-1c to form an elongated conductive structure. Similarly, one or more of the other elongated ground pads, such as the second elongated ground pad 302-2 and the first elongated ground pad 302-3, can include a plurality of ground pads and one or more conductive bars electrically connecting adjacent ones of the ground pads. For example, the first elongated ground pad 302-3 can include a first ground pad 302-3a, a second ground pad 302-3b, and a conductive bar 302-3c that extends between the first ground pad 302-3a and the second ground pad 302-3b.

Therefore, the radio frequency filter packaging structure may be particularly useful where there is a standard manufacturing step for a packaging structure with multiple ground pads already present, as it allows the structure to be formed by adding only a minor step of merging the ground pads. Furthermore, the merging of ground pads may allow an existing packaging structure with multiple ground pads to be easily modified to form the elongated ground pads, thereby minimizing changes to the manufacturing process.

It will be appreciated that the elongated ground pad does not necessarily have to be formed by merging separate ground pads. Alternatively, for one or more of the elongated ground pads, the entire elongated ground pad may be formed as a single, continuous structure without the need for merging separate ground pads and conductive bars.

It will be appreciated that, as used herein, a feature positioned “near” a referenced side of a substrate can mean that the feature is located closer to the referenced side than to at least one other side of the substrate. For example, a feature positioned “near” a referenced side of a substrate can mean that the feature is located closer to the referenced side than to any other sides of the substrate. A feature positioned “near” a referenced side can mean that the feature is located within a threshold distance from the referenced side, where the threshold distance can be selected based on a pad pitch, a keep-out distance, and/or a target isolation level.

Forming the elongated ground pad as a single, continuous structure may be particularly advantageous if the existing manufacturing methods and/or facilities can be readily adapted to accommodate such formation. In particular, forming the elongated ground pad in a single step, instead of requiring multiple steps of separately forming ground pads and subsequently connecting them with a conductive bar, may reduce manufacturing complexity and costs. Moreover, an elongated ground pad formed in a single step may exhibit improved mechanical integrity or electrical performance compared to one formed by merging separate ground pads.

The first elongated ground pad 302-3 has a first maximum lateral dimension, the second elongated ground pad 302-1 has a second maximum lateral dimension, and the second elongated ground pad 302-2 has a third maximum lateral dimension. In some embodiments, the first maximum lateral dimension of the first elongated ground pad 302-3 can be greater than a maximum lateral dimension of the first signal pad 304-1, a maximum lateral dimension of the first signal pad 304-2, a maximum lateral dimension of the second signal pad 306-1, and/or a maximum lateral dimension of the second signal pad 306-2. For example, the first maximum lateral dimension of the first elongated ground pad 302-3 can be at least 1.2 times, 1.5 times, 2 times, 3 times, or 5 times greater than the maximum lateral dimension of the first signal pad 304-1. Similarly, the second maximum lateral dimension and the third maximum lateral dimension can be greater than a maximum lateral dimension of the third signal pad 308-1 and/or a maximum lateral dimension of the fourth signal pad 308-2.

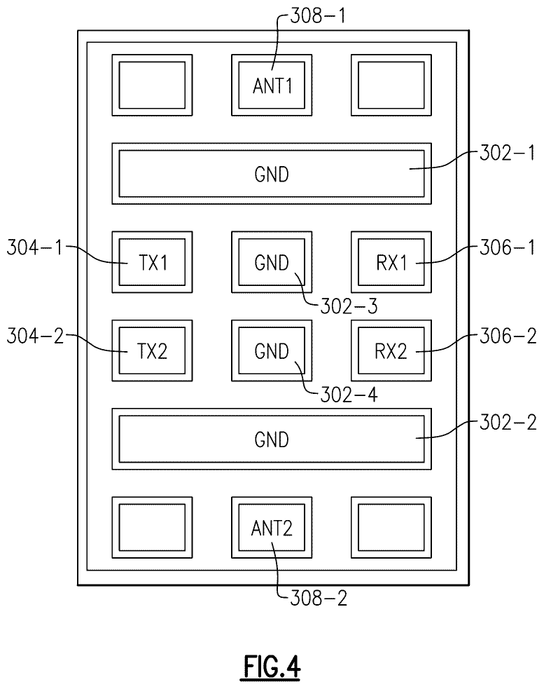

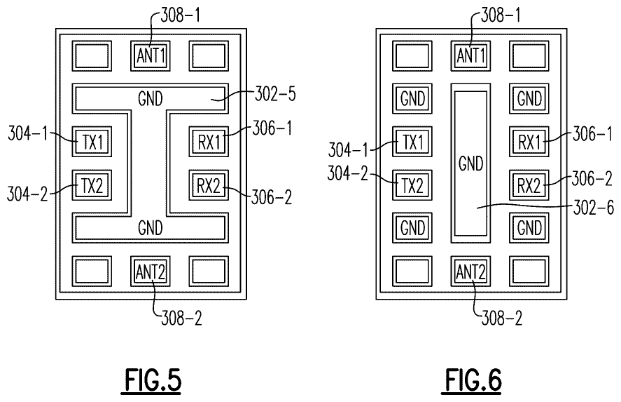

FIG. 4 illustrates a top view of another example of a radio frequency filter packaging structure that is similar to the example shown in FIG. 3A but differs in the configuration of the ground pads 302-4. In the example of FIG. 3A, a single second elongated ground pad 302-3 extends across a length covering the entire span of the first signal pads 304-1, 304-2 and the second signal pads 306-1, 306-2, thereby providing isolation between the first signal pads and the second signal pads. In contrast, the radio frequency filter packaging structure illustrated in FIG. 4 can include the ground pads 302-4 between the second elongated ground pads 302-1, 302-2.

As shown in the examples of FIGS. 3A-3C and FIG. 4, the radio frequency filter packaging structure may comprise a plurality of elongated ground pads, such as the first elongated ground pad 302-3 and/or one or more second elongated ground pads 302-1, 302-2. Thus, it may be advantageous to merge at least some of the elongated ground pads 302-1, 302-2, 302-3, and the ground pads 302-4. Such merging may provide an integrated elongated ground pad with improved isolation, as the integrated elongated ground pad formed by merging multiple elongated ground pads may cover a wider area between signal pads 304-1, 304-2, 306-1, 306-2, 308-1, 308-2. Additionally, merging ground pads can simplify the manufacturing process, as it provides a structure having a lower number of elongated ground pads to achieve the same or similar isolation effect.

In relation to the examples of FIGS. 3A-3C and FIG. 4, such an integrated elongated ground pad may be formed by merging the second elongated ground pads 302-1, 302-2 and the first elongated ground pad 302-3 or the ground pads 302-4, which may result in an “I”-shaped integrated elongated ground pad 302-5 (see FIG. 5). As discussed above, such an integrated elongated ground pad may also be formed in a single step.

In cases where the integrated elongated ground pad is formed in a single step, mold flow characteristics can be taken into account. In particular, if mold flow is used to form the integrated elongated ground pad 302, there may be challenges in achieving adequate mold flow to the distal corners of the integrated elongated ground pad if the mold flow is introduced from the middle of the integrated elongated ground pad 302. To address this issue, the corresponding manufacturing step may be designed to ensure adequate coverage. For example, by introducing mold flow from multiple locations across the integrated elongated ground pad and/or by adjusting the temperature and duration of the corresponding manufacturing step. Additionally, the shape and dimensions of the integrated elongated ground pad may be designed to facilitate uniform mold flow and prevent or mitigate insufficient coverage at distal regions.

As discussed in relation to the above example of the “I”-shaped integrated elongated ground pad, a plurality of elongated ground pads on the first surface of the substrate (e.g., the first elongated ground pads 302-3, 302-4 and the second elongated ground pads 302-1, 302-2) may be provided in the form of an integrated ground pad.

FIG. 5 is a schematic plan view of a radio frequency filter packaging structure that includes the “I”-shaped integrated elongated ground pad 302-5. In such configurations, the integrated ground pad 302-5 may comprise at least one first elongated portion positioned between the first signal pad 304-1 and the second signal pad 306-1. This first elongated portion may serve to provide electromagnetic isolation between the first signal pad 304-1 and the second signal pad 306-1, thereby enhancing the isolation performance of the radio frequency filter packaging structure. Additionally, the integrated ground pad 302-5 may comprise at least one second elongated portion positioned between the third signal pad 308-1 and the fourth signal pad 308-2. The second elongated portion may be configured to provide electromagnetic isolation between the third signal pad 308-1 and the fourth signal pad 308-2. This arrangement allows the integrated ground pad 302-5 to simultaneously provide isolation between different sets of signal pads, thereby contributing to improved overall isolation performance. As discussed above, the use of an integrated ground pad 302-5 with distinct elongated portions may simplify the manufacturing process by reducing the need for multiple separate ground pads and connections. In particular, forming the integrated ground pad 302-5 in a single step may enable more efficient manufacturing and consistent electrical performance across the ground pads.

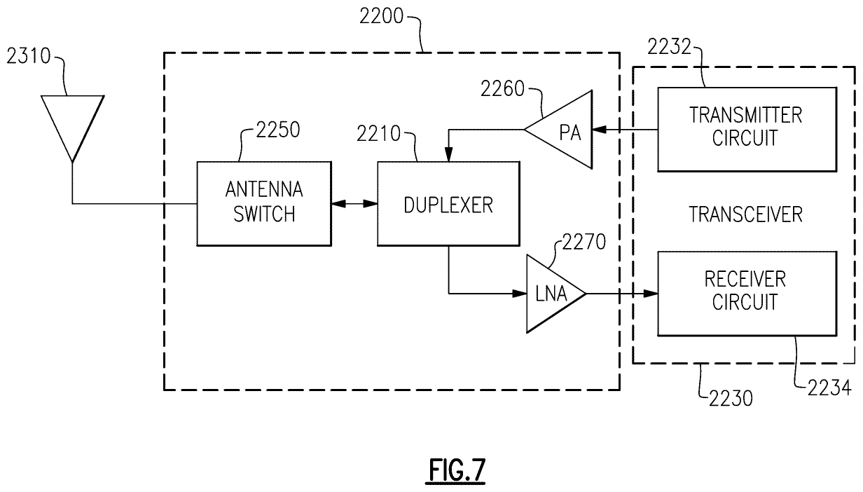

FIG. 6 is a schematic plan view of a radio frequency filter packaging structure that includes an integrated elongated ground pad 302-6 having another shape. The integrated elongated ground pad 302-6 can effectively provide an isolation wall between the first signal pad 304-1 (e.g., a first transmit port) and the second signal pad 306-1 (e.g., a first receive port) and/or between the first signal pad 304-2 (e.g., a second transmit port) and the second signal pad 306-2 (e.g., a second receive port).

It will also be appreciated that the integrated elongated ground pad 302 may be provided in any other suitable shape to provide isolation between corresponding signal pads. For example, the integrated elongated ground pad 302 may be configured in a “+” shape or a “T” shape. In some embodiments, pads in a radio frequency filter packaging structure may include one or more ground pads between the first signal pads 304-1, 304-2, or the second signal pads 306-1, 306-2, and selected one or more ground pads may merge to define such shapes.

Referring back to FIG. 5, the first elongated portion of the integrated ground pad 302-5 may have a width equal to or wider than the first signal pad 304-1 and the second signal pad 306-1 to ensure effective isolation between them. Similarly, the second elongated portion of the integrated elongated ground pad 302-5 may have a width equal to or wider than the third signal pad 308-1 and the fourth signal pad 308-2 to ensure effective isolation between these signal pads.

In embodiments where a plurality of elongated ground pads (e.g., the first and second elongated ground pads) are provided as separate components rather than as an integrated elongated ground pad, the first elongated ground pad 302-3 may have a width equal to or wider than the first signal pad 304-1 and the second signal pad 306-1 to ensure effective isolation. Similarly, the second elongated ground pad 302-1, 302-2 may have a width equal to or wider than the third signal pad 308-1 and the fourth signal pad 308-2 to ensure effective isolation.

The substrate may comprise one or more interconnects. In such cases, at least one of the interconnects may be electrically connected to the ground. One or more of the interconnects may optionally be provided near the first or second surface of the substrate, or within an interior layer of the substrate. One or more of the interconnects may facilitate electrical connections between the ground and various components of the radio frequency filter packaging structure.

For example, the first elongated ground pad 302-3 may be electrically connected to at least one of the interconnects that is electrically connected to the ground. Optionally, the first elongated ground pad 302-3 may be electrically connected to the one or more interconnects by one or more vias. Optionally, the first elongated ground pad 302-3 may be electrically connected to the ground via the interior layer of the substrate, with the electrical connection to the interior layer being provided by one or more vias.

Similarly, the second elongated ground pad 302-1, 302-2 may be electrically connected to at least one of the interconnects that is electrically connected to the ground. Optionally, the second elongated ground pad 302-1, 302-2 may be electrically connected to the one or more interconnects by one or more vias. Optionally, the second elongated ground pad 302-1, 302-2 may be electrically connected to the ground via the interior layer of the substrate, with the electrical connection to the interior layer being provided by one or more vias.

The ground connection may optionally be coupled to the first elongated ground pad 302-3 away from the substrate. Similarly, the ground connection may be coupled to the second elongated ground pad 302-1, 302-2 away from the substrate. Therefore, according to a number of embodiments, configurations that enable flexible routing of ground connections without being limited by the substrate layout may be provided.

The substrate may also comprise other materials with low-loss dielectric properties. This may be advantageous for minimizing signal attenuation and improving performance of the radio frequency filter packaging structure. The substrate may comprise a layer having a multilayer organic and/or ceramic structure. The electrical connections formed within the interior layer of the substrate may be configured to route signals between the signal pads and external circuitry.

The radio frequency filter packaging structure described above may be used in a power amplifier duplexer module. Such a power amplifier duplexer module may include a transmitter component connected to the first signal pad 304-1, 304-2, a receiver component connected to the second signal pad 306-1, 306-2, a first antenna connected to the third signal pad 308-1, and a second antenna connected to the fourth signal pad 308-2.

In such a power amplifier duplexer module, the at least one first elongated ground pad 302-3 may be positioned to form an isolation wall between the first signal pad 304-1 and the second signal pad 306-1. Similarly, the at least one second elongated ground pad 302-1, 302-2 may be positioned to form an isolation wall between the third signal pad 308-1 and the fourth signal pad 308-2. This configuration may enhance isolation performance between the transmitter and receiver components, as well as between the first and second antennas, thereby improving the overall performance of the power amplifier duplexer module.

Such a power amplifier duplexer module may be a low-band power amplifier duplexer module. In such an embodiment, the first antenna and the second antenna may be configured to receive signals of different frequency bands, allowing the power amplifier duplexer module to support multi-band communication.

The power amplifier duplexer module may further comprise a plurality of third signal pads 308-1, 308-2, each of which may be connected to a different transmitter component. This configuration may facilitate the transmission of signals across multiple frequency bands by enabling separate connections for each transmitter component. Similarly, the power amplifier duplexer module may comprise a plurality of fourth signal pads 308-3, 308-4, each of which may be connected to a different receiver component. This arrangement may enable the reception of signals across different frequency bands by providing separate connections for each receiver component.

Similarly, it will be appreciated that the radio frequency filter packaging structure described above may be used in a mobile communication device or a wireless mobile device. In such applications, the radio frequency filter packaging structure may facilitate signal transmission and reception across multiple frequency bands. Integration of multiple elongated ground pads for improved isolation may be useful for reducing interference between different signal paths, thereby improving signals handled by such applications.

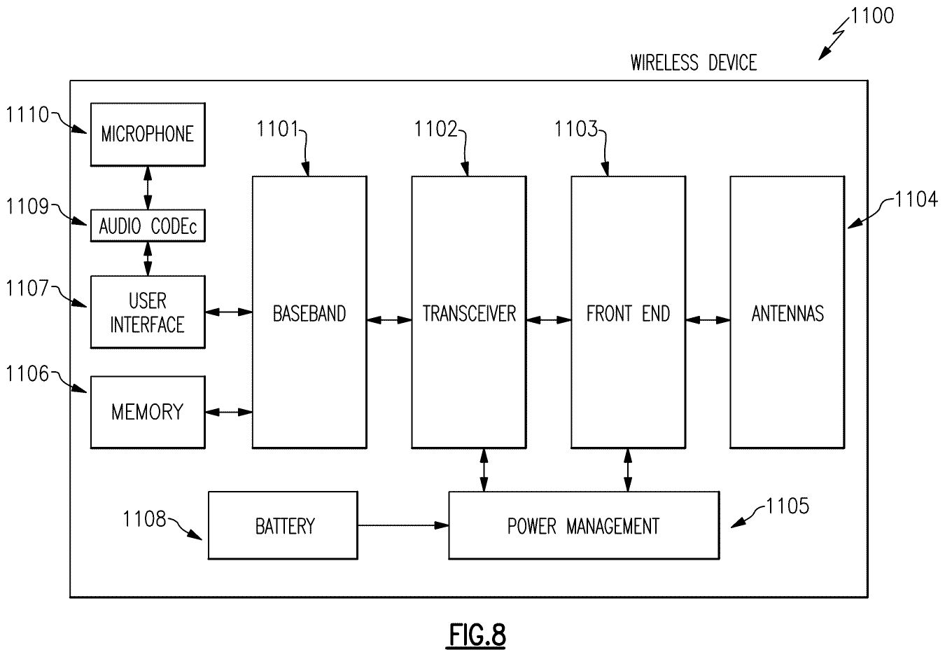

The radio frequency filter packaging structure may also be included in an acoustic device. An exemplary acoustic device is shown in FIG. 8. The radio frequency filter packaging structure may also be included in a radio-frequency front end (RFFE) module. An exemplary RFFE module is shown in FIG. 7. This figure illustrates a front-end module 2200, connected between an antenna 2310 and a transceiver 2230. The front-end module 2200 includes a duplexer 2210 in communication with an antenna switch 2250, which itself is in communication with the antenna 2310.

As illustrated, the transceiver 2230 comprises a transmitter circuit 2232. Signals generated for transmission by the transmitter circuit 2232 are received by a power amplifier (PA) module 2260 within the front-end module 2200, which amplifies the generated signals from the transceiver 2230. The PA module 2260 can include one or more PAs. The PA module 2260 can be used to amplify a wide variety of RF or other frequency-band transmission signals. For example, the PA module 2260 can receive an enable signal that can be used to pulse the output of the PA to aid in transmitting a wireless local area network (WLAN) signal or any other suitable pulsed signal. The PA module 2260 can be configured to amplify any of a variety of types of signals, including, for example, a Global System for Mobile (GSM) signal, a code division multiple access (CDMA) signal, a W-CDMA signal, a Long-Term Evolution (LTE) signal, or an EDGE signal.

In certain embodiments, the PA module 2260 and associated components, including switches and the like, can be fabricated on gallium arsenide (GaAs) substrates using, for example, high electron mobility transistors (pHEMT) or insulated-gate bipolar transistors (BiFET), or on a silicon substrate using complementary metal-oxide semiconductor (CMOS) field effect transistors (FETs).

Still referring to FIG. 7, the front-end module 2200 may further include a low noise amplifier (LNA) module 2270, which amplifies received signals from the antenna 2310 and provides the amplified signals to the receiver circuit 2234 of the transceiver 2230.

FIG. 8 is a schematic diagram of a wireless device 1100 that can incorporate aspects of the disclosure. The wireless device 1100 can be, for example, but not limited to, a portable telecommunication device such as a mobile cellular-type telephone. The wireless device 1100 can include a microphone arrangement 1110, and may include one or more of a baseband system 1101, a transceiver 1102, a front-end system 1103 (such as the front-end module 2200 of FIG. 7), one or more antennas 1104, a power management system 1105, a memory 1106, a user interface 1107, a battery 1108, and an audio codec 1109. The microphone arrangement may supply signals to the audio codec 1109, which may encode analog audio as digital signals or decode digital signals to analog. The audio codec 1109 may transmit the signals to a user interface 1107. The user interface 1107 transmits signals to the baseband system 1101. The transceiver 1102 generates RF signals for transmission and processes incoming RF signals received from the antennas. The front-end system 1103 aids in conditioning signals transmitted to and/or received from the antennas 1104. The antennas 1104 can include antennas used for a wide variety of types of communications. For example, the antennas 1104 can include an antenna for transmitting and/or receiving signals associated with a wide variety of frequencies and communications standards. The baseband system 1101 is coupled to the user interface to facilitate processing of various user input and output, such as voice and data. The baseband system 1101 provides the transceiver 1102 with digital representations of transmit signals, which the transceiver 1102 processes to generate RF signals for transmission. The baseband system 1101 also processes digital representations of received signals provided by the transceiver 1102.

As shown in FIG. 8, the baseband system 1101 is coupled to the memory 1106 to facilitate operation of the wireless device 1100. The memory 1106 can be used for a wide variety of purposes, such as storing data and/or instructions to facilitate the operation of the wireless device 1100 and/or to provide storage of user information. The power management system 1105 provides a number of power management functions for the wireless device 1100. The power management system 1105 receives a battery voltage from the battery 1108. The battery 1108 can be any suitable battery for use in the wireless device, including, for example, a lithium-ion battery.

Having described above several aspects of at least one embodiment, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A radio frequency filter packaging structure comprising:
a substrate having a first surface and a second surface;
a plurality of signal pads disposed on the first surface, the signal pads including a first signal pad positioned near a first side of the substrate, a second signal pad positioned near a second side of the substrate which is located away from the first side, a third signal pad positioned near a third side of the substrate, and a fourth signal pad positioned near a fourth side of the substrate which is located away from the third side;
at least one first elongated ground pad disposed on the first surface and positioned between the first signal pad and the second signal pad;
at least one second elongated ground pad disposed on the first surface and positioned between the third signal pad and the fourth signal pad; and
a ground connection via which the first and second elongated ground pads electrically connected to a ground.

2. The radio frequency filter packaging structure of claim 1 wherein the first elongated ground pad includes at least two first ground pads and a conductive bar extending between the at least two first ground pads.

3. The radio frequency filter packaging structure of claim 1 wherein the second elongated ground pad includes at least two second ground pads and a conductive bar extending between the at least two second ground pads.

4. The radio frequency filter packaging structure of claim 1 wherein the first and second elongated ground pads are provided as an integrated ground pad.

5. The radio frequency filter packaging structure of claim 1 wherein the first elongated ground pad has a width equal to or wider than the first and second signal pads.

6. The radio frequency filter packaging structure of claim 1 wherein the second elongated ground pad has a width equal to or wider than the third and fourth signal pads.

7. The radio frequency filter packaging structure of claim 1 wherein the substrate includes a ground plane electrically connected to the ground.

8. The radio frequency filter packaging structure of claim 1 wherein the substrate includes one or more interconnects, at least one of the one or more interconnects being electrically connected to the ground, and the first elongated ground pad is electrically connected to the at least one of the one or more interconnects electrically connected to the ground.

9. The radio frequency filter packaging structure of claim 1 wherein the ground connection is coupled to the first elongated ground pad away from the substrate.

10. The radio frequency filter packaging structure of claim 1 wherein the substrate includes a layer having a multilayer organic and/or ceramic structure.

11. A power amplifier duplexer module comprising:
a radio frequency filter packaging structure, the radio frequency filter packaging structure including:
a substrate having a first surface and a second surface,
a plurality of signal pads disposed on the first surface, the signal pads including a first signal pad positioned near a first side of the substrate, a second signal pad positioned near a second side of the substrate located away from the first side, a third signal pad positioned near a third side of the substrate, and a fourth signal pad positioned near a fourth side of the substrate located away from the third side,
at least one first elongated ground pad disposed on the first surface and positioned between the first signal pad and the second signal pad,
at least one second elongated ground pad disposed on the first surface and positioned between the third signal pad and the fourth signal pad, and
a ground connection via which the first and second elongated ground pads electrically connected to a ground;
a transmitter component connected to the first signal pad;
a receiver component connected to the second signal pad;
a first antenna connected to the third signal pad; and
a second antenna connected to the fourth signal pad.

12. The power amplifier duplexer module of claim 11 wherein the first antenna and the second antenna are configured to receive signals of different frequency bands.

13. A radio frequency device comprising:
a first transmit-receive pad pair including a first transmit signal pad and a first receive signal pad;
a second transmit-receive pad pair including a second transmit signal pad and a second receive signal pad; and
a ground pad structure including a first portion having a first ground pad, a second ground pad, and a conductive bar extending between the first ground pad and the second ground pad, the first portion positioned between the first transmit signal pad and a first receive signal pad.

14. The radio frequency device of claim 13 wherein the first portion of the ground pad structure is positioned between the second transmit signal pad and the second receive signal pad.

15. The radio frequency device of claim 13 wherein the ground pad structure further includes a second portion having a third ground pad, a fourth ground pad, and a second conductive bar extending between the third ground pad and the fourth ground pad.

16. The radio frequency device of claim 15 wherein the first portion and the second portion are electrically coupled by a third conductive bar.

17. The radio frequency device of claim 15 further comprising a carrier portion and a device portion coupled to the carrier portion, wherein the first portion and the second portion are located on a surface of the carrier portion opposite the device portion, and the first portion and the second portion are electrically coupled by a ground interconnect structure embedded in the carrier portion.

18. The radio frequency device of claim 13 wherein a maximum lateral dimension of the first portion of the ground pad structure is greater than a maximum lateral dimension of the first transmit signal pad.

19. The radio frequency device of claim 18 wherein the maximum lateral dimension of the first portion is at least 1.5 times greater than the maximum lateral dimension of the first transmit signal pad.

20. The radio frequency device of claim 13 further comprising a first antenna pad and a second antenna pad, wherein the ground pad structure is at least partially positioned between the first antenna pad and the second antenna pad.
